(19) United States
(12) Patent Application Publication
(10) Pub. No.: US 2003/0096459 A1
(43) Pub. Date: May 22, 2003

(54) Crystalline silicon thin film transistor panel for LCD and method of fabricating the same

(76) Inventors: Seung Ki Joo, Seongnam-si (KR); Seok-Woon Lee, Incheon (KR)

Correspondence Address: GRAYBEAL, JACKSON, HALEY LLP, 155 - 108TH AVENUE NE, SUITE 350, BELLEVUE, WA, 98004-5901, US

(21) Appl. No.: 10/290,048

(22) Filed: Nov. 6, 2002

(30) Foreign Application Priority Data
Nov. 6, 2001 (KR) 2001-68979

(51) Int. Cl. H01L 21/00

(52) U.S. Cl. 438/149

(57) ABSTRACT

The present invention relates to a crystalline silicon TFT panel for LCD and a method of fabricating the same. According to the present invention, a pixel transistor and a storage capacitor, which include a crystalline silicon thin film, are formed at a pixel region of the TFT panel using MILC, and a driving transistor is also formed at a driving circuit region of the TFT panel. Furthermore, two or more gate electrodes are formed at the pixel transistor so as to effectively lower an off current of the pixel transistor. Thus, the present invention has an advantage in that semiconductor devices required in the pixel region and the driving circuit region of the TFT panel for LCD can be simultaneously fabricated through a relatively simple process, and thus, an off current characteristic and an on current characteristic that are required in the pixel region and the driving circuit region, respectively, can be simultaneously satisfied.

### PRIORITY CLAIM

This application claims priority from Korean patent application No. 2001-68979, filed Nov. 6, 2001, which is herein incorporated by reference.

### BACKGROUND OF THE INVENTION

1. Field of the Invention

The present invention relates to a crystalline silicon thin film transistor (TFT) panel for use in a TFT LCD and method of fabricating the same. More particularly, the present invention relates to a crystalline silicon TFT panel for a TFT LCD and method of fabricating the same, wherein a pixel transistor located at a pixel region of the TFT panel and a driving transistor located at a peripheral region are simultaneously formed from crystalline silicon, and a low off current (Ioff) characteristic of the transistor required in the pixel region and a high on current (Ion) characteristic of the transistor constituting the driving circuit formed in the peripheral region are all satisfied, using metal induced lateral crystallization (MILC).

2. Description of the Prior Art

There is a problem in that amorphous silicon TFT, which has been usually used in the conventional LCD, can be easily fabricated on a glass substrate at a process temperature of 350° C. or lower, but cannot be used in a high-speed operation circuit since the electron mobility of amorphous silicon is low. Further, in the LCD using the amorphous silicon TFT, the pixel transistors should be formed in the substrate, and the glass substrate and a PCB should also be connected with each other around the substrate using a TCP (tape carrier package) driving IC. Therefore, there are other problems in that an additional driving IC is required and the mounting cost is increased. Furthermore, there is a further problem in that a connection portion between the TCP driving IC and the PCB or a connection portion between the TCP driving IC and the glass substrate is disconnected by mechanical and thermal shock, or contact resistance at the connection portion is increased. In addition, there is a still further problem in that the TCP bonding itself becomes difficult since a pad pitch between a signal line and a scanning line is shorten as the resolution of the LCD panel is increased.

As for the LCD using the crystalline silicon TFT, however, the crystalline silicon can be used in a driving circuit of a switching device etc. of the LCD since the crystalline silicon constituting an active layer of the TFT has good electron mobility. Thus, the pixel transistor and the driving transistor can be simultaneously formed on the TFT panel. Further, as the crystalline silicon TFT has a self-aligned structure, the level shift voltage thereof is lower than that of the amorphous silicon TFT. Also, it is possible to form a CMOS circuit since an N channel and a P channel can be formed using the crystalline silicon in the crystalline silicon TFT. In addition, the process of fabricating the crystalline silicon TFT can be employed in a semiconductor production line since it is similar to the standard CMOS process for a silicon wafer.

FIG. 1 is a schematic view of the TFT panel for LCD 10 on which the pixel region 11 and the peripheral regions, i.e. the driving circuit region 12 are formed. Arrays of a plurality of pixels including the pixel transistor, a storage capacitor, and the like are formed in the pixel region 11, and driving devices for driving the pixels are formed in the driving circuit region 12. In the crystalline silicon TFT LCD, a hybrid-driving mode in which analog circuits such as an operation amplifier (OP amplifier) or a digital-analog converter (DAC), which it is difficult to fabricate using the crystalline silicon TFT, are used as separate integrated circuits and the switching device such as a multiplexer is formed on the substrate are usually employed instead of forming all the driving devices on the substrate.

FIG. 2 is an equivalent circuit diagram illustrating a structure of a unit pixel formed at the pixel region of the TFT panel for LCD 10. Each of the unit pixels includes a data bus line (Vd); a gate bus line (Vg); a pixel transistor 21 having a gate connected to the gate bus line, and source and drain connected to the data bus line and the pixel electrode; a storage capacitor 22 (Cst) for maintaining a state of a signal applied to the pixel transistor 21 until a next signal is applied; and a liquid crystal injection unit 23 (C_{LC}) connected in parallel to the storage capacitor 22. At this time, the storage capacitor 22 and the liquid crystal injection unit 23 are each connected to a common electrode 24 (Vcom).

As for the crystalline silicon TFT panel for LCD in which the pixel region and the driving circuit region are simultaneously formed in the common substrate, it is required that the pixel region have the low off current (Ioff), i.e. a current flowing into the pixel transistor in a state where a gate voltage is not applied, whereas the driving circuit region have the high on current (Ion), i.e. a current flowing into the thin film transistor in a state where the gate voltage is applied, in order to effectively drive the driving device such as the switching device. Referring to FIG. 2, particularly, in a case where the off current of the pixel transistor 21 is high, the driving voltage applied to the liquid crystal injection unit 23 cannot be maintained until a next signal period since electric charges accumulated in the storage capacitor 22 are leaked. Thus, there is a problem in that display stability and uniformity are significantly degraded.

The thin film transistor of the TFT panel for use in the crystalline silicon LCD is fabricated by forming an amorphous silicon layer on the glass substrate and then crystallizing the amorphous silicon by means of solid phase crystallization, laser crystallization, direct deposition method, rapid thermal annealing, or the like. One of the characteristics of the present invention is that a method of crystallizing the active layer of the thin film transistor using the metal induced lateral crystallization (MILC) is used instead of the existing method of crystallizing the amorphous silicon. If the MILC is used, there is an advantage in that the crystalline silicon TFT can be simultaneously formed at the pixel region and the peripheral region through a simple process at a relatively low temperature as compared with the existing crystallization method. However, similarly to the crystalline silicon crystallized by another method, the crystalline silicon crystallized by the MILC exhibits a high off current as compared with the amorphous silicon. In particular, in order to preserve electrical signals accumulated at the pixels during a non-select period in the pixel region without any loss, it is generally required that the off current be lower than 1E-11 A. However, the crystalline silicon TFT which has been formed using the MILC exhibits a good on current characteristic and a poor off current characteristic (that is, the off current is relatively high). Thus, there is another problem in that the thin film transistor characteristic required in the pixel region cannot be satisfied.

Accordingly, there are needs for a structure of the crystalline silicon TFT panel and method of fabricating the same, in which the crystalline silicon TFT is effectively formed at the pixel region and the driving circuit region of the TFT panel for LCD at the same time, and the low off current required in the pixel region and the high on current required in the peripheral regions are simultaneously satisfied.

### SUMMARY OF THE INVENTION

The present invention is conceived to solve the problems in the prior art. An object of the present invention is to provide a thin film transistor (TFT) panel and method of fabricating the same, wherein a pixel transistor and a driving transistor including a crystalline silicon active layer are simultaneously formed at a pixel region and a driving circuit region, respectively, of the TFT panel for LCD using metal induced lateral crystallization (MILC), and an off current characteristic and an on current characteristic that are required in the pixel region and the driving circuit region, respectively, are simultaneously satisfied.

### BRIEF DESCRIPTION OF THE DRAWINGS

FIG. 1 is a schematic view showing region positioning of a TFT panel for LCD;

FIG. 2 is an equivalent circuit diagram illustrating a structure of a unit pixel in the TFT panel for LCD;

FIGS. 3a to 3d are sectional views illustrating a conventional method of fabricating a thin film transistor using MILC;

FIG. 4 is a graph illustrating variation in a drain current depending on the number of a gate in the TFT fabricated using the MILC; and

FIGS. 5a to 5p are sectional views illustrating a process of fabricating a crystalline silicon TFT panel for LCD according to the present invention.

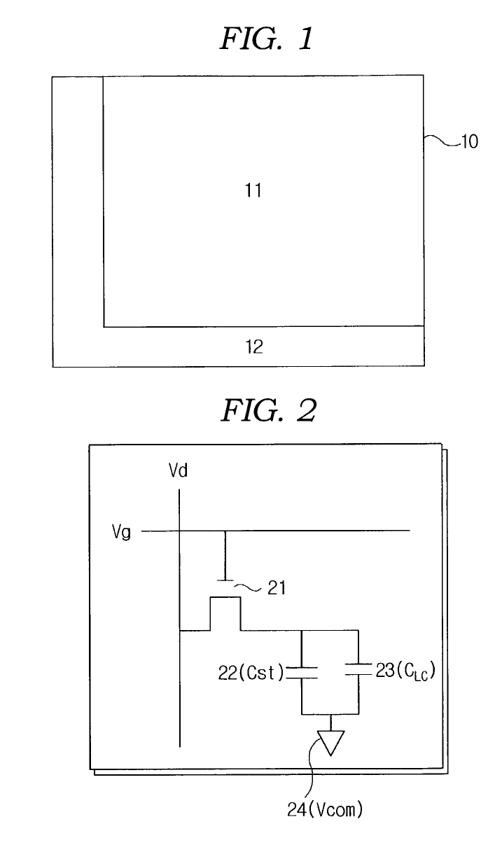

### DESCRIPTION OF THE PREFERRED EMBODIMENTS

Before explaining the specific constitution of the present invention, a process of forming a crystalline silicon thin film transistor using MILC will be now described below.

A thin film transistor for use in a display device such as LCD is usually constructed in such a manner that silicon is deposited on a transparent substrate made of glass, quartz, or the like; gates and gate electrodes are formed thereon; dopants are implanted into source and drain regions and are activated in a process of annealing; and then an insulating layer is formed thereon. An active layer for constituting the source and drain regions and a channel of the thin film transistor is generally formed by depositing a silicon layer onto the transparent substrate made of glass using a chemical vapor deposition (CVD) method, sputtering, and the like. However, the silicon layer deposited directly onto the substrate by using a method such as the CVD is an amorphous silicon layer, and thus, has low electron mobility. As the display device employing the thin film transistors requires a fast operating speed and is miniaturized, the degree of integration of driving integrated circuits (ICs) is increased and an aperture ratio of a pixel area is decreased. Thus, it is necessary to simultaneously form the driving circuits and the pixel transistors and to increase the pixel aperture ratio by improving the electron mobility of the silicon layer. To this end, a technique for forming a crystalline silicon layer having high electron mobility by means of crystallization of the amorphous silicon layer through the annealing thereof has been utilized.

Various methods for crystallizing the amorphous silicon layer into the polysilicon layer of the thin film transistor have been proposed. Solid phase crystallization (SPC) is a method for annealing the amorphous silicon layer for several hours to several tens of hours at a temperature of about 600° C. or lower that is a transition temperature of glass used for forming the substrate. Since the SPC method requires a long period of time for thermal annealing the silicon layer, there is a problem in that productivity thereof is low. Further, if the substrate has a large area, the substrate may be deformed during the process of long thermal annealing even at a temperature of 600° C. or lower. Excimer laser crystallization is a method for instantaneously crystallizing the silicon layer by scanning the silicon layer using the excimer laser beam onto to generate high temperature thereon locally for a very short period of time. The ELC method has a technical difficulty in precisely controlling the scanning of the laser beam and can fabricate only one substrate at one time. Therefore, there is also a problem in that productivity of the ELC method becomes lower than a case where several substrates are batch processed in a furnace.

In order to overcome the shortcoming of the conventional method for crystallizing the silicon layer, it is utilized a phenomenon in which a phase change of the amorphous silicon into the polysilicon is induced even at a low temperature of about 200° C. when metals such as nickel, gold and aluminum come into contact with or implanted into the amorphous silicon. Such a phenomenon is called as metal induced crystallization (MIC). In a case where the thin film transistor has been fabricated using the MIC phenomenon, any metal remains in the polysilicon for constituting the active layer of the thin film transistor. Thus, there is a problem in that current leakage occurs particularly at the channel of the thin film transistor. Recently, there has been proposed a method for crystallizing the silicon layer using metal induced lateral crystallization (MILC) in which crystallization of the silicon is successively induced while silicide formed by reaction of the metal and silicon is continuously, laterally propagated, without allowing the metals to directly induce phase change of the silicon (S. W. Lee & S. K. Joo, IEEE Electron Device Letter, 17(4), p. 160, 1996). Nickel, palladium, and the like are specifically known as the metals for inducing the MILC. In a case where the silicon layer is crystallized using the MILC, a metal component used for inducing the crystallization of the silicon hardly remains within the silicon layer, which is crystallized through the MILC, since an interface of the metal-containing silicide propagates laterally as the crystallization of the silicon layer is propagated. Thus, there is an advantage in that the metals such as Ni and Pd have no influence on the current leakage characteristics and other operating characteristics of the active layer of the thin film transistor. In addition, by utilizing the MILC, the crystallization of the silicon can be induced even at a relatively low temperature of 300° C. to 500° C. Thus, there is another advantage in that the furnace can be used so that several sheets of the substrates are simultaneously crystallized without damage to the substrates. In addition, in a case where the MILC phenomenon is used, it is possible to induce crystallization of silicon even at a relatively low temperature of 300° C. to 600° C. Thus, there is an advantage in that several sheets of the substrates can be simultaneously crystallized using the furnace without any damage to the substrate even though a general glass substrate is used.

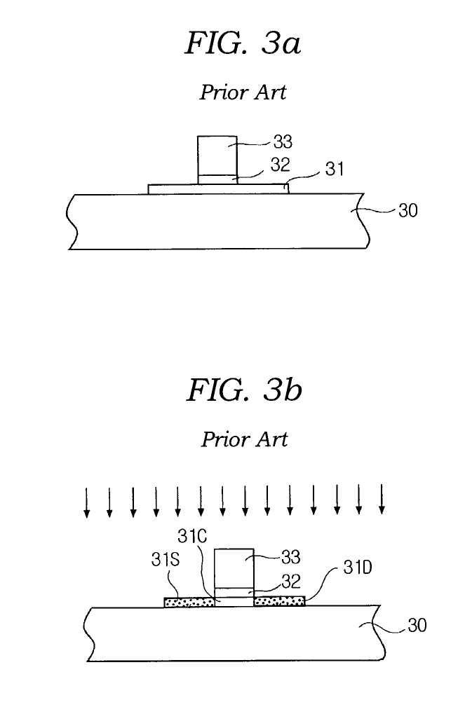

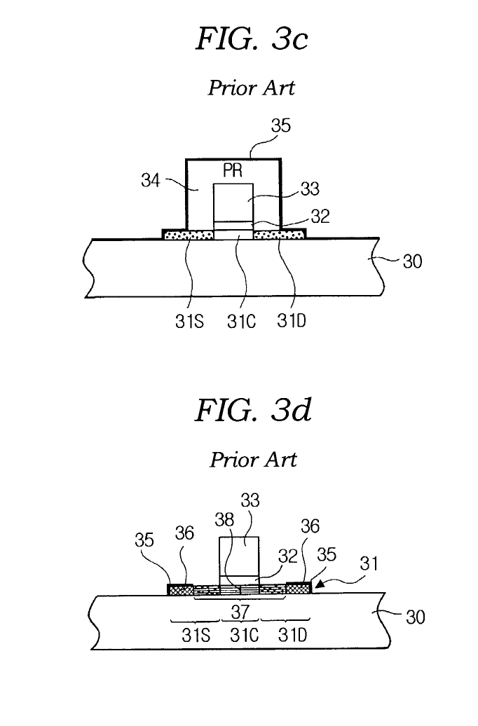

FIGS. 3a to 3d are sectional views showing a conventional process of crystallizing the silicon layer constituting TFT using the MIC and MILC phenomena. As shown in FIG. 3a, an amorphous silicon layer 31 is deposited on an insulating substrate 30 with a buffer layer (not shown) formed thereon. Then, amorphous silicon is patterned by photolithography to form an active layer 31. Next, a gate insulating layer 32 and a gate electrode 33 are sequentially formed on the active layer 31 by means of a general method. As shown in FIG. 3b, a source region 31S, a channel region 31C and a drain region 31D are formed on the active layer 31 by doping an impurity into an entire substrate in a state where the gate electrode 33 is used as a mask. As shown in FIG. 3c, a photoresist 34 (PR) is formed such that the gate electrode 33 and some portions of the source region 31S and the drain region 31D around the gate electrode are covered. A metal layer 35 is then deposited on an entire surface of the photoresist and substrate. As shown in FIG. 3d, the photoresist 34 is removed and the entire substrate is then annealed at a temperature of 300 to 600° C. Thus, a source and drain region 36 right below the remaining metal layer 35 is crystallized by the MIC phenomenon, whereas a metal-offset portion of the source and drain region and a channel region 37 just below the gate electrode are induced to be crystallized by means of the MILC phenomenon which will be induced from the remaining metal layer 35.

In FIGS. 3a to 3d, the reason that the photoresist is formed to cover the source and drain regions 31S, 31D at both sides of the gate electrode 33 is that the metal components introduced by the MIC phenomenon remains in the channel region 31C and at the boundaries between the channel region 31C and the source/drain regions 31S, 31D if the metal layer is deposited up to the boundaries and thus a leakage current from and an operating characteristic of the channel region may be degraded. Since the source and drain regions except for the channel region are not greatly affected by the remaining metal components in view of their operations, the source and drain regions spaced apart from the channel region by about 0.01 to 5 μm are caused to be crystallized through the MIC phenomenon while crystallization for only the channel region and the channel driving circuit region is caused to be induced by the MILC phenomenon, so that crystallization time is reduced.

As can be seen from Table 1, in a case where when a single gate is used as shown in FIGS. 3a to 3d, the thin film transistor including the crystalline silicon active layer, which has been crystallized by the MILC phenomenon according to the method shown in the figures, has an on current of about 3.00E-4 A and an off current of about 5.00E-11 A. Therefore, the ratio of the on current and off current (Ion/Ioff) becomes about 6.00E+06. It is generally known that problems such as flicker and cross talk occur if the off current of the pixel transistor for use in the LCD is greater than 1E-11 A. Consequently, since the crystalline silicon thin film transistor in which only one gate is employed in the crystalline silicon crystallized by the MILC has the off current greater than the aforementioned value of 1E-11 A, the crystalline silicon thin film transistor may be difficult to be used as the pixel transistor for the LCD. On the other hand, since as seen from Table 1, the on current is about 3.00E-4 A in a case where only one gate is used, it is greater than an on current range of 1E-05 A, which is generally required in the pixel transistor for the LCD. Therefore, if the crystalline silicon TFT formed by the MILC is to be used in the pixel region, the off current should be kept less than 1E-11 A while maintaining the on current at a level greater than 1E-05 A.

In the crystalline silicon TFT fabricated using the MILC, if the number of the gate is increased, a junction distance between the source and drain regions is increased and intensity of an electric field applied to the junction region is accordingly weaken. Thus, it is possible to reduce the off current. Although the on current is reduced as the number of the gate becomes increased, a degree of reduction in the on current is significantly smaller than that of the off current. Table 1 below shows variations in the off current, the on current, and the ratio of the on current and the off current according to the increase in the number of the gate.

TABLE 1

| | Number of Gate | | |
|---|---|---|---|
| | 1 | 2 | 4 |
| Ioff(A) | 5.00E−11 | 8.00E−12 | 4.00E−13 |
| Ion(A) | 3.00E−04 | 2.00E−04 | 1.00E−04 |
| Ion/Ioff | 6.00E+06 | 2.50E+07 | 2.50E+08 |

(It is a measurement result when a width W of the transistor=10 μm, a length L thereof=6 μm, V_{D}=10V, Ion is measured at the gate voltage V_{G}=20V; and Ioff is measured at the gate voltage V_{G}=−5V)

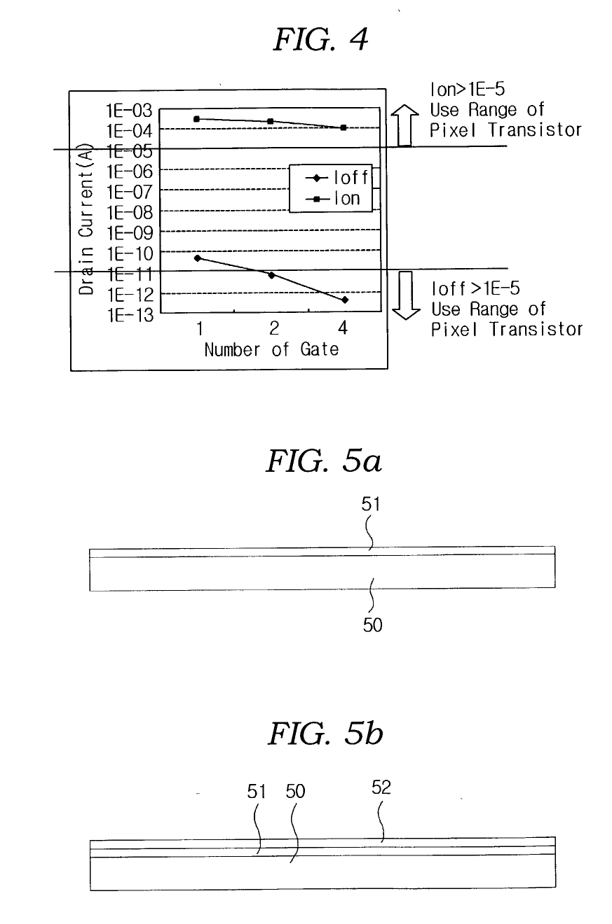

FIG. 4 is a graph illustrating the variations in the on current and off current according to the number of the gate depicted in Table 1. As seen from Table 1 and FIG. 4, if the number of the gate is increased to 2 and 4, the off current is changed to 8.00E-12 A and 4.00E-13 A, respectively. Thus, it will be understood that the off current, which is less than 1E-11 A required in the pixel transistor of the LCD, can be obtained if two or more gates are employed in the TFT. Meanwhile, it can be seen that the on current of 1.00E-04 A, which is greater than the on current 1E-5 A generally required in the pixel transistor of the LCD, can be obtained even when four gates are employed, because a rate of reduction in the on current according to the increase in the number of the gate is relatively low. Accordingly, it can be seen that the ratio of the on current and the off current (Ion/Ioff) is continuously increased as the number of the gate becomes increased. From the above results, it can be seen that the crystalline silicon TFT fabricated by the MILC according to the present invention can simultaneously satisfy the requirement characteristics of the on current and the off current in the pixel transistor of the LCD, i.e. Ion>1E-5 and Ioff<1E-11, if the two or more gates are used. Further, the on current corresponding to when the number of the gate shown in Table 1 and FIG. 4 is two or more has a current level enough to support the operation of the driving device formed at the driving circuit region of the substrate. Thus, it can be seen that the method of fabricating the crystalline silicon TFT using the MILC according to the present invention can be preferably used to simultaneously form the pixel transistor on the pixel region and the driving transistor on the driving circuit region of the LCD substrate, in a case where two or more gates are formed in the TFT of the pixel region.

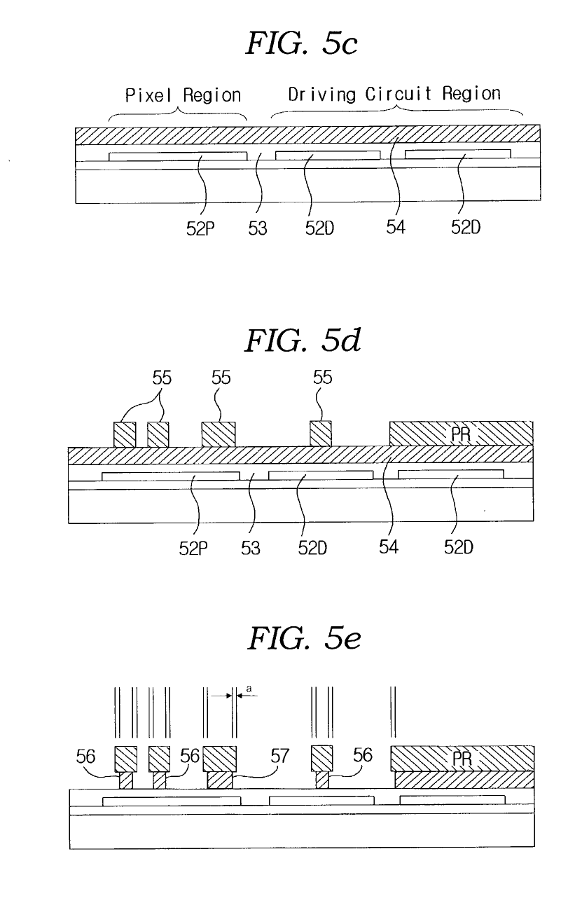

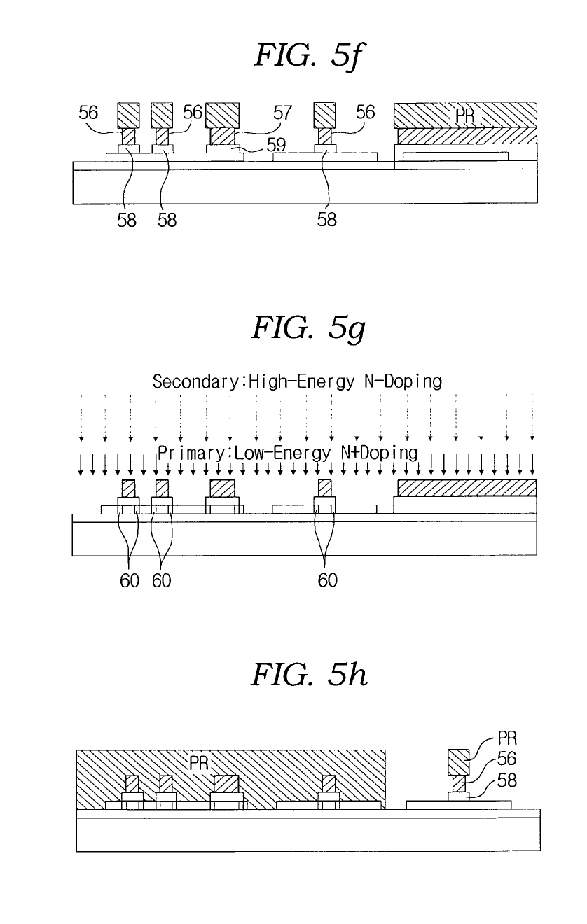

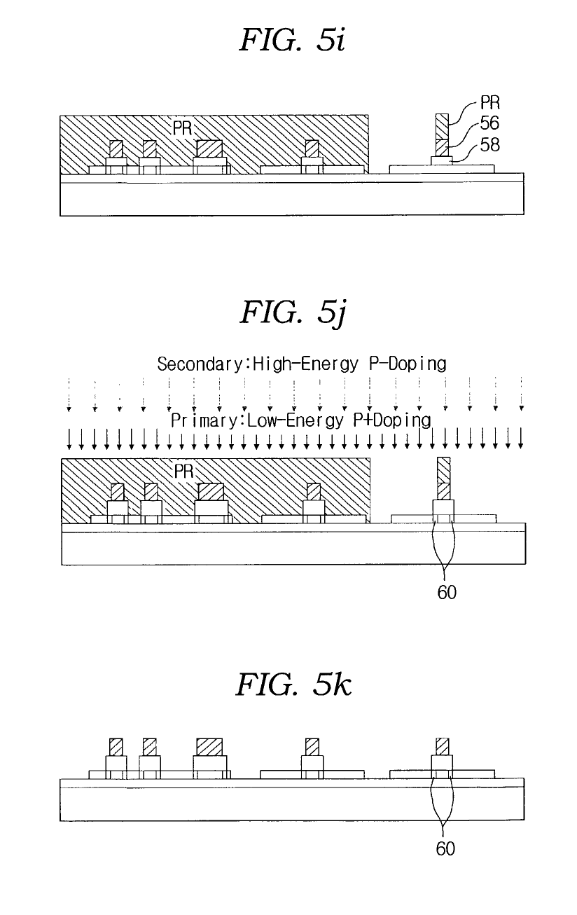

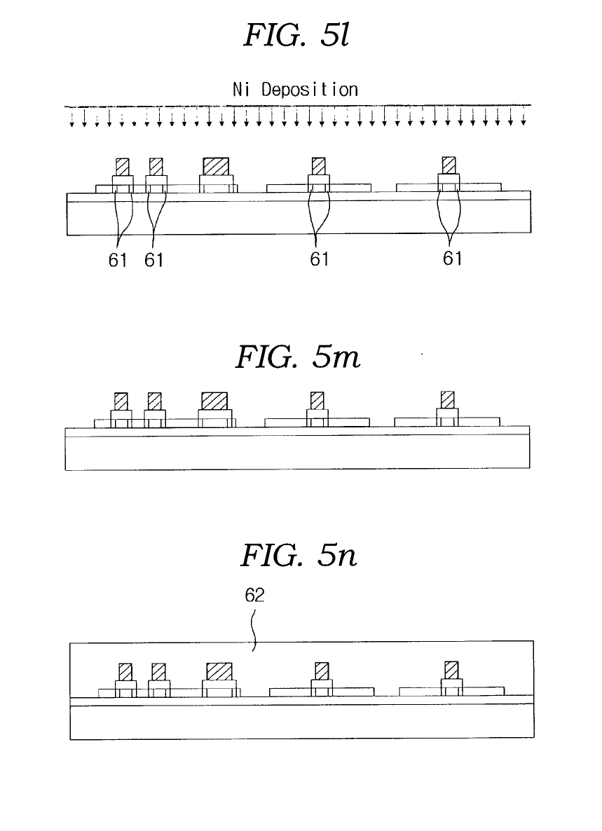

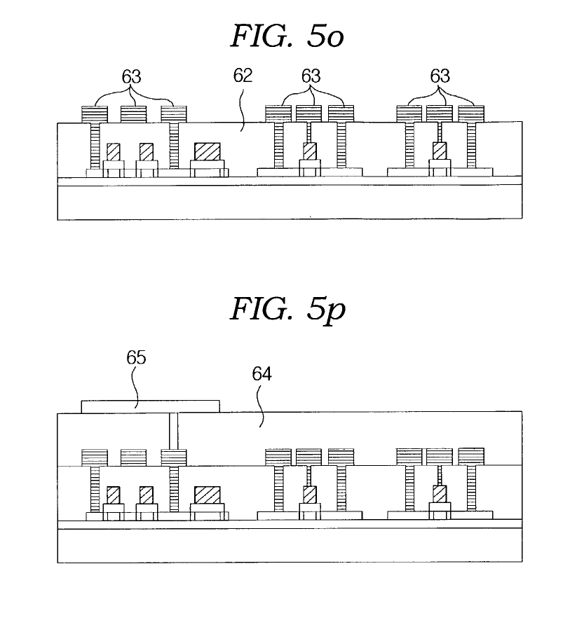

A process of simultaneously forming the pixel transistor and the driving transistor in the TFT panel using the MILC according to a preferred embodiment of the present invention will be hereinafter explained with reference to FIGS. 5a to 5p. Although an example in which one pixel transistor and one storage capacitor are formed in the pixel region and a CMOS transistor is formed in the driving circuit region will be described below, it should be understood that the present invention is not limited thereto. According to the present invention, for example, two or more TFTs may be formed in the pixel region, and P-MOS, N-MOS, CMOS or combination thereof may be formed in the driving region. Further, although it has been described in a preferred embodiment that the silicon layers of the pixel transistor and the storage capacitor are connected with each other, it is apparent to those skilled in the art that the silicon layers of the pixel transistor and the storage capacitor need not necessarily be physically connected with each other but they may be configured to be electrically connected with each other. Furthermore, although it has been described in the preferred embodiment that an electrode of the storage capacitor is formed from the crystalline silicon, other layers such as the metal layer may be substituted for the electrode. Moreover, it is apparent to those skilled in the art that a dielectric layer of the storage capacitor may be formed from a layer that is made of a material different from the gate insulating layer, for example, an intermediate insulating layer.

FIG. 5a is a sectional view showing a state where a shield layer 51 for preventing diffusion of contaminants from a substrate 50 is formed on the substrate 50. Here, the substrate 50 is made of a transparent insulating material such as non-alkali glass, quartz, silicon oxide, or the like. The shield layer 51 is formed by depositing silicon oxide (SiO₂), silicon nitride (SiNx), silicon oxynitride (SiOₓN_{y}) or the composite material thereof at temperature of about 600° C. or lower and to thickness of 300 to 10,000 Å, more preferably 500 to 3,000 Å, using a deposition method such as plasma-enhanced chemical vapor deposition (PECVD), low-pressure chemical vapor deposition (LPCVD), atmospheric pressure chemical vapor deposition (APCVD), or electron cyclotron resonance CVD (ECR-CVD), or sputtering method.

As shown in FIG. 5b, an amorphous silicon layer 52 (a-Si) constituting the active layer of the thin film transistor is formed on the shield layer 51. The amorphous silicon layer 52 is formed by depositing the amorphous silicon to thickness of 100 to 3,000 Å, more preferably 500 to 1,000 Å, using the PECVD, LPCVD or sputtering method. Next, in order to form a N-MOS or a P-MOS in the pixel region and a CMOS used as the driving device in the driving circuit region as shown in FIG. 5c, the amorphous silicon layer is patterned by dry etching using plasma of etching gas, by using the pattern formed by the photolithography. In FIG. 5b, the pixel region and the driving circuit region are shown to be adjacent to each other. However, in an actual substrate, arrays of a plurality of unit pixels are formed in the pixel region, and a driving circuit is formed to be spaced apart from the unit pixel arrays. Meanwhile, it should be noted that one unit pixel region and one driving circuit region are shown to be connected with each other in the figures, in order to illustrate the process of simultaneously forming the pixel transistor and the driving transistor. In the preferred embodiment, a single amorphous silicon island 52P is formed in the pixel region in order to form one N-MOS or P-MOS, whereas two amorphous silicon islands 52D are formed in the driving circuit region in order to form the CMOS. Although an example in which the CMOS is formed in the driving circuit region is described in the preferred embodiment, various kinds of driving circuits including N-MOS, P-MOS, CMOS or combination thereof can be formed in the driving circuit region, if necessary.

After the amorphous silicon 52 is patterned, an insulating layer 53 in which a gate insulating layer will be formed and a metal layer 54 in which a gate electrode will be formed are formed as shown FIG. 5c. The insulating layer 53 is formed by depositing silicon oxide (SiO₂), silicon nitride (SiNx), silicon oxynitride (SiOₓN_{y}) or a composite layer thereof to thickness of 300 to 3,000 Å, preferably 500 to 1,000 Å, using the deposition method such as PECVD, LPCVD, APCVD, or ECR CVD. Further, the gate metal layer 54 is formed by depositing a metal material or a conductive material such as a doped polysilicon onto the insulating layer 53 to thickness of 1,000 to 8,000 Å, preferably 2,000 to 4,000 Å, using the method such as sputtering, evaporation, PECVD, LPCVD, APCVD, or ECR CVD.

FIGS. 5d and 5e show a process of forming a gate electrode 56 and a capacitor electrode 57 through a wet or dry etching process after forming photoresist patterns 55 which are formed through the photolithography onto the gate metal layer 54 located above an amorphous silicon island 52P in which the pixel transistor will be formed and the amorphous silicon island 52D in which a driving transistor will be formed. As shown in the figures, three electrodes are formed in the pixel region, one gate electrode is formed above the amorphous silicon island 52D located at the left side of the driving circuit region, and an entire surface of the amorphous silicon island region located at the right side of the driving circuit region is covered with the photoresist (PR) so as to form other kinds of TFTs constituting the CMOS. Two left electrodes 56 among the three electrodes formed in the pixel region are used to form a dual gate electrode of the pixel transistor, and the other right electrode 57 is used as an electrode of the storage capacitor connected to the pixel transistor. In the preferred embodiment, the reason that the dual gate electrode is formed in the pixel transistor is that the off current can be further reduced since the junction between the source and drain regions is extended and the intensity of the electric field applied to the junction is weaken when multiple gates are used. Although the preferred embodiment of the present invention is configured to have two gates formed in the pixel transistor, it should be noted that the dual gate and/or two or more gates can be used in the driving transistor.

As shown in FIG. 5e, the preferred embodiment of the present invention is configured to have an undercut structure by over etching the gate electrode 56 by a predetermined distance a inwardly of the patterned photoresist. As described below, the gate electrode layer is over etched so that a low-concentration doped region such as an LDD (lightly doped drain) region can be formed around the channel region below the gate electrode of the transistor.

FIG. 5f shows a state where a gate insulating layer 58 and a dielectric layer 59 of the capacitor have been formed by isotropically etching the insulating layer 53, using the patterned photoresist as a mask. Since the gate electrode has been over-etched against the photoresist as described above, the gate insulating layer 58 and the dielectric layer 59 are formed to have a width greater than that of the gate electrode 56 and the capacitor electrode 57 as shown in FIG. 5f.

FIG. 5g shows a process during which an impurity is doped using the gate electrode as a mask in a state where the photoresist has been removed. First, high-concentration impurity doping is performed with low energy onto the pixel transistor and the left driving transistor that is not covered with the photoresist. For example, if a N-MOS TFT is to be fabricated as shown in the figure, dopants such as PH₃, P, or As are doped at a dose of approximately 1E14 to 1E22/cm³ (preferably, 1E15 to 1E21/cm³) with energy of 10 to 100 KeV (preferably, 10 to 30 KeV), using an ion shower doping or ion implantation method. On the other hand, if a P-MOS TFT is to be fabricated, dopants such as B₂H₆, B, or BH₃ are doped at a dose of approximately 1E13 to 1E22/cm³ (preferably, 1E14 to 1E21/cm³) with energy of 10 to 70 KeV (preferably, 10 to 30 KeV). FIG. 5g shows a process of implanting the N-type impurity for the purpose of illustration. Since the high-concentration impurity is doped with low energy, it does not pass through the gate insulating layer. Thus, the source and drain regions of the thin film transistor are formed in a state where the impurity is implanted into only a region which is not covered with the gate insulating layer. According to the present invention, since the gate insulating layer in the pixel transistor is wider than the gate electrode and also serves to prevent the impurity doped at a high concentration with low energy from being implanted into the silicon layer, the low-concentration doped region having low impurity concentration can be formed around the channel region. Further, the gate insulating layer serves to form a metal offset region around the channel region, which will be described later.

After the low-energy high-concentration doping is performed, a high-energy low-concentration doping is performed. At this time, if the N-MOS TFT is to be fabricated, the high-energy low-concentration doping is performed in such a manner that the dopants such as PH₃, P and As at a dose of 1E11 to 1E20/cm³ with energy of 50 to 150 KeV, using the ion shower doping method, the ion implantation method or the other ion implantation methods. On the other hand, if the P-MOS TFT is to be fabricated, the high-energy low-concentration doping is performed in such a manner that dopants such as B₂H₆, B, and BH₃ at a dose of 1E11 to 1E20/cm³ with energy of 20 to 100 KeV. Since the low-concentration doping is performed with an energy level enough to allow the low-concentration impurity to pass through the gate-insulating layer, a low-concentration doped region 60 doped with the low concentration is formed at the active layer region covered with the gate-insulating layer.

Although it has been described that the low-energy high-concentration doping is performed and the high-energy low-concentration doping is then performed, it is apparent to those skilled in the art that a doping order may be changed. Meanwhile, if the high-concentration impurity is implanted with the high energy, the high-concentration impurity is injected into the silicon layer through the gate insulating layer. Therefore, the low-concentration doped region is not formed around the channel. Further, if the high-energy low-concentration doping process is omitted from the above process, an offset junction into which an impurity is not injected can be formed in the driving circuit region of the thin film transistor channel, instead of the low-concentration doped region. Furthermore, in order to form the low-concentration doped region, the low-energy high-concentration doping method may be used instead of the high-energy low-concentration doping method. In such a case, the doping energy is controlled so that most of the impurities are confined within the insulating layer and only a portion of the impurities can be injected into the silicon layer.

If the low-concentration doped region or the offset junction is formed in the drain region adjacent the channel, the off current of the transistor can be reduced and the other electrical characteristics can also be stabilized. In order to accomplish these advantageous effects, it is preferred that the low-concentration doped region or the offset junction be configured to have a width of 1,000 to 20,000 Å, preferably 5,000 to 20,000 521 . It was found that to maintain the concentration of the impurity injected into the low-concentration doped region to be less than 1E14/cm² is particularly effective in reducing the off current of the pixel transistor to 1E-11 A or lower. Therefore, it is preferred that the impurity concentration in the low-concentration doped region be regulated to be less than 1E14/cm² by adjusting the doping energy and the dopant dose. In the preferred embodiment, the low-concentration doped region is formed in both the pixel transistor and the driving transistor. However, it should be noted that the low-concentration doped region may not be formed in the driving transistor since it is less necessary to critically limit the off current in the driving transistor as compared with the offset current in the pixel transistor.

After the process of FIG. 5g has been completed, the gate insulating layer 58 and the gate electrode 56 are formed using the same method as described with reference to FIGS. 5d to 5f in order to form the P-type transistor at one side of the CMOS transistor, in a state that the entire pixel regions and the one transistor (N-type transistor in the preferred embodiment) located at the other side of the CMOS transistor formed in the driving region are covered with the photoresist (PR) as shown in FIG. 5h. Although it has been described in the preferred embodiment that the N-type transistor is first formed and the P type transistor is then formed in order to form the CMOS transistor of the driving region, it is apparent that the order of forming the transistors may be changed. As shown in FIG. 5i, the photoresist located above the gate electrode is then etched back so that the width of the photoresist is almost equal to that of the gate electrode.

Referring to FIG. 5j, after the gate insulating film and the gate electrode of the CMOS transistor located at the one side, i.e. the P type transistor are patterned as shown FIG. 5i, an impurity of an opposite polarity (i.e., P-type) to the other transistor constituting the CMOS transistor is first doped at high concentration with low energy and is then doped at low concentration with high energy, in the same manner as described with reference to FIG. 5g. As described above, the impurity doped at the low concentration with the high energy is injected into the silicon layer through the gate insulating layer, and thus, the low-concentration doped region is formed around the channel region of the P-type transistor. Of course, the execution order of the low-energy high-concentration doping and the high-energy low-concentration doping may be changed. In addition, the offset junction may be formed around the channel instead of the low-concentration doped region by omitting the high-energy doping process. Although it has been described in the preferred embodiment that the low-concentration doped region is formed in both the pixel transistor and the driving transistor, it should be noted that the low-concentration doped region may not be formed in the driving transistor since the driving transistor does not require the off current characteristic to a level necessary for the pixel transistor.

FIG. 5k shows a state where the photoresist, which has been used as the mask in the doping process, has been removed; and FIG. 5l shows a process during which the photoresist is removed from the entire area of the pixel and driving regions on the substrate and a metal for inducing the MILC is then applied for crystallizing the amorphous silicon constituting the active layer of the transistor. Preferably, the metal for causing the MILC phenomenon to be induced into the amorphous silicon may include nickel (Ni) or palladium (Pd). Besides, Ti, Ag, Au, Al, Sn, Sb, Cu, Co, Cr, Mo, Tr, Ru, Rh, Cd, Pt or the like can be used. In the preferred embodiment, Ni is used as the metal for inducing the MILC. The metal for inducing the MILC such as Ni or Pd can be applied to the active layer through the sputtering, evaporation, PECVD or ion implantation method. But, the sputtering method is generally used. At this time, thickness of the applied metal layer may be arbitrarily selected within a range sufficient for inducing the MILC of the amorphous silicon layer, i.e. about 1 to 10,000 Å, preferably 10 to 200 Å.

As shown in FIG. 5l, a metal offset region 61 on which the metal for inducing the MILC is not deposited is formed around the channel region of each of the transistors on the substrate, because the gate insulating layer covers around the channel region. As already described with reference to FIGS. 3a to 3d, the metal offset region 61 serves to prevent a metal component, which is introduced into the silicon layer by means of the MIC phenomenon occurring at a region on which the metal for inducing the MILC such as Ni is directly deposited, from generating the current leakage in the channel region and degrading the operating characteristics. In the preferred embodiment, the gate insulating layer that has been patterned to be wider than the gate electrode serves to simultaneously form the low-concentration doped region and the metal offset region around the channel region. Therefore, the low-concentration doped region 60 and the metal offset region 61 are formed at the same region. Although it has been described in the preferred embodiment that the low-concentration doped region and the metal offset region are formed using the patterned gate insulating layer, it should be noted that the metal offset region may be formed by using the photoresist mask formed before the metal for inducing the MILC is applied, as shown in FIG. 3. Therefore, the low-concentration doped region and the metal offset region are not necessarily overlapped with each other at the same region, and the low-concentration doped region may be formed at a portion of the metal offset region or vice versa.

After Ni is applied on the transistors in the pixel region and the driving region, an annealing process for crystallizing the active layer of the transistor is performed, as shown FIG. 5m. The crystallization-annealing process may be performed according to any given methods by which the MILC phenomenon can be induced into the amorphous silicon. The method may include, for example, a rapid thermal annealing (RTA) method in which the active layer is heated during a short period of time within several seconds to several minutes at a temperature of about 500 to 1200° C. using a tungsten-halogen or xenon arc heating lamp or an ELC method in which the active layer is heated during a very short period of time using an excimer laser. In the present invention, the crystallization of the silicon is preferably performed in a furnace at a temperature of 400 to 600° C. during 0.1 to 50 hours, more preferably during 0.5 to 20 hours. Since temperature when the amorphous silicon is crystallized in the furnace is lower than the glass transition temperature of the glass substrate, any transformation of or damage to the substrate can be prevented. Further, since a lot of the substrates can be simultaneously annealed in the furnace, mass processing of the substrate can be made. Therefore, the productivity thereof is increased. The crystallization at the amorphous silicon region to which the metal for inducing the MILC is directly applied through the annealing process is performed by the MIC phenomenon, whereas the crystallization at the portion to which the metal is not applied is performed by the MILC phenomenon propagated from the region to which the metal is applied. Further, according to the present invention, the crystallization of the active layer and the dopant may be performed in a single process since the annealing condition for crystallizing the amorphous silicon by means of the metal for inducing the MILC is similar to the annealing condition for activating the dopant injected into the active layer.

The amorphous silicon layer in the storage capacitor region, which is connected to the drain of the pixel transistor and formed at a lateral side of the pixel transistor, is simultaneously crystallized through the annealing process. One of the characteristics of the present invention is that the storage capacitor and the pixel transistor are simultaneously formed to have the same structure using the same process. The storage capacitor exhibits good static capacitance and static characteristics since it is configured to have a structure that the dielectric layer 59 made of the same material as the gate insulating layer of the pixel transistor is mounted between the crystalline silicon layer 52P with good electron mobility and the capacitor electrode 57 made of the same material as the gate electrode.

As shown in FIG. 5n, an intermediate insulating layer 62 is formed after the active layer of the transistor in the pixel and driving regions of the substrate has been crystallized. The intermediate insulating layer 62 is formed by depositing silicon oxide, silicon nitride, silicon oxynitride or composite layer thereof to thickness of 1,000 to 15,000 Å, more preferably 3,000 to 7,000 Å, using the deposition methods such as PECVD, LPCVD, APCVD, ECR CVD or sputtering.

FIG. 5o shows a state where a contact electrode 63 is formed. Referring to FIG. 5o, a contact hole is formed by wet or dry etching the intermediate insulating layer using the pattern formed by the photolithography as a mask. The contact electrode 63 for connecting the source, drain and gate of the transistor to external circuits is then formed. The contact electrode 63 is formed by depositing the metal or the conductive material such as doped polysilicon onto the entire intermediate insulating layer to thickness of 500 to 10,000 Å, more preferably 2,000 to 6,000 Å, using the sputtering, evaporation, CVD method, and the like, and then patterning the metal or the conductive material to have a desired shape through the dry or wet etching method.

Thereafter, an insulating film 64 for covering the contact electrode is formed and then patterned according to a general method. A pixel electrode 65 for applying the electric field to the liquid crystal in the LCD unit pixel is formed at the pixel transistor region. Thus, the TFT panel for use in the LCD is completed, as shown in FIG. 5p. According to the aforementioned process, the crystalline pixel transistor having two gate electrodes and the storage capacitor connected to the pixel transistor are formed at the pixel region of the LCD substrate using the MILC, and the crystalline driving transistor such as the CMOS are simultaneously formed at the driving region using the low-temperature process.

Although the present invention has been described with reference to a preferred embodiment, it is merely an example of the present invention but should not be construed to limit the technical scope of the present invention. It is apparent to those skilled in the art that the present invention can be modified or changed in various modes within the scope of the present invention.

For example, although it has been described in the preferred embodiment that two gate electrodes are formed in the pixel transistor, it should be noted that more gate electrodes can be formed, if necessary, within the scope of the present invention. Further, although it has been described that the CMOS is formed in the driving region, the driving circuit comprising the various types of the thin film transistors such as P-MOS, N-MOS and CMOS or combination thereof can be formed in the driving region. In addition, although it has been described in the preferred embodiment that a single gate electrode is formed in the driving transistor, two or more gate electrodes can be formed therein. Furthermore, although it has been described that the gate patterns of the N-TFT and the P-TFT are separately formed and impurities are also separately injected into the N-TFT and the P-TFT, it should be noted that the gate patterns may be simultaneously formed and the N-TFT and the P-TFT may be formed in such a manner that the P-FTF region is masked by the photoresist etc. when the N-TFT impurity is injected therein, and that the N-FTF region is also masked by the photoresist when the N-TFT impurity is injected therein. Of course, it is apparent that these additional mask processes are not required if all the TFTs such as the pixel transistor and the driving transistor are to be formed using only one type of TFT. Moreover, although it has been described above that the electrode of the storage capacitor is formed from the crystalline silicon, the electrode can be replaced by the other layer such as the metal layer. It is also apparent to those skilled in the art that the dielectric layer of the storage capacitor may be formed using a layer made of a material different from that of the gate insulating layer, e.g. the intermediate insulating layer.

As described above, according to the present invention, there is an advantage in that a pixel transistor, a storage capacitor and a driving device can be simultaneously formed in a TFT panel, using MILC, at low temperature at which the substrate for use in a display device such as an LCD cannot be damaged. Further, there is another advantage in that the TFT panel of the present invention can meet an on current characteristic required in the pixel transistor and the driving device of the LCD and can also effectively reduce an off current of the pixel transistor below a required level by forming two or more gates in the pixel transistor. In addition, there is a further advantage in that a low-concentration doped region and a metal offset region can be formed in the transistors of the TFT panel through a simple process, and thus, the operating characteristics of the pixel transistor and the driving device can be further improved.

What is claimed is:

1. A thin film transistor (TFT) panel for use in a TFT LCD, comprising:
a transparent substrate including a pixel region having a plurality of unit pixels and a driving circuit region;
a pixel transistor which is formed at every unit pixel of the pixel region in the substrate and includes a crystalline silicon active layer, a gate insulating layer and a gate electrode, said active layer being crystallized by metal induced lateral crystallization (MILC);
a storage capacitor formed at every unit pixel of the substrate; and
a plurality of driving transistors which are formed in the driving circuit region of the substrate and include a crystalline silicon active layer crystallized by the MILC, a gate insulating layer and a gate electrode,
wherein at least two or more gate electrodes are formed in the pixel transistor.

2. The TFT panel as claimed in claim 1, wherein the transparent substrate is a glass substrate.

3. The TFT panel as claimed in claim 1, wherein the pixel transistor comprises an N-MOS or P-MOS and the driving transistor comprises a CMOS.

4. The TFT panel as claimed in claim 1, wherein at least two or more gate electrodes are formed in the driving transistor.

5. The TFT panel as claimed in claim 1, wherein the gate insulating layer in the pixel transistor is at least wider than the gate electrode, and a low-concentration doped region having impurity concentration of 1E14/cm² or lower is formed around a channel region of the pixel transistor by performing low-energy high-concentration doping using the gate insulating layer as a mask and high-energy low-concentration doping using the gate electrode as the mask.

6. The TFT panel as claimed in claim 1, wherein the MILC is performed through a process of applying a metal for inducing the MILC to an amorphous silicon layer and annealing the layer in a state where the gate insulating layers of the pixel transistor and the driving transistor are formed to be wider than the gate electrode and then the gate electrode and the gate insulating layer are used as a mask.

7. The TFT panel as claimed in claim 6, wherein the metal for inducing the MILC is applied by depositing at least one of Ni, Pd, Ti, Ag, Au, Al, Sn, Sb, Cu, Co, Cr, Mo, Tr, Ru, Rh, Cd and Pt to thickness of 1 to 200 Å using sputtering, evaporation or CVD method, and the annealing process is performed in a furnace at a temperature of 400 to 600° C. for 0.1 to 50 hours.

8. The TFT panel as claimed in claim 1, wherein a shield layer for preventing impurity diffusion is formed on the transparent substrate before the pixel transistor, the storage capacitor and the driving transistor are formed.

9. The TFT panel as claimed in claim 1, further comprising an intermediate insulating layer and a patterned contact electrode, which are formed on the pixel transistor, the storage capacitor and the driving transistor.

10. The TFT panel as claimed in claim 1, wherein the storage capacitor includes an crystalline silicon layer crystallized by the MILC, and a dielectric layer and a capacitor electrode which are sequentially formed on the crystalline silicon layer; the crystalline silicon layer of the pixel transistor and the crystalline silicon layer of the storage capacitor are connected with each other; the gate insulating layer of the pixel transistor and the dielectric layer of the capacitor are simultaneously formed from the same material; and the gate electrode of the pixel transistor and the capacitor electrode are simultaneously formed from the same material.
